(19) United States
(12) Patent Application Publication
(10) Pub. No.: US 2012/0050654 A1
(43) Pub. Date: Mar. 1, 2012

(54) SENSOR ARRAY SUBSTRATE AND DISPLAY DEVICE HAVING THE SAME

(75) Inventors: Dong-Kwon KIM, Asan-si (KR); Nam-Heon KIM, Yongin-si (KR); Kwang-Hoon LEE, Anyang-si (KR)

(73) Assignee: SAMSUNG ELECTRONICS CO., LTD., Suwon-si (KR)

(21) Appl. No.: 13/211,763

(22) Filed: Aug. 17, 2011

(30) Foreign Application Priority Data
Aug. 25, 2010 (KR) 10-2010-0082558

(51) Int. Cl. G02F 1/133; H01L 31/0216

(52) U.S. Cl. 349/116; 257/435; 257/E31.122

(57) ABSTRACT

A sensor array substrate includes: a substrate; a protective substrate disposed on a first surface of the substrate; a plurality of light sensor units disposed on a second surface of the substrate, where the plurality of light sensor units detects reflection light reflected from a surface of the protective substrate; and a reflection light blocking pattern disposed between the light sensor units and the protective substrate, where the reflection light blocking pattern blocks a portion of the reflection light, and where a plurality of openings corresponding to the plurality of light sensor units is formed in the reflection light blocking pattern.

This application claims priority to Korean Patent Application No. 10-2010-0082558, filed on Aug. 25, 2010, and all the benefits accruing therefrom under 35 U.S.C. §119, the content of which in its entirety is herein incorporated by reference.

### BACKGROUND OF THE INVENTION

1. Field of the Invention

The general inventive concept relates to a sensor array substrate and a display device having the sensor array substrate.

2. Description of the Related Art

A display device having a sensor array substrate typically receives data input by touching its screen using a finger, a pen or the like. The types of the display device having a sensor array substrate may include a resistive type display device, a capacitive type display device and an optical sensor type display device, for example, according to the operation methods.

The resistive type display device is typically operated by a contact generated between electrodes when a predetermined pressure is applied. The capacitive type display device is typically operated using a variation in electrostatic capacitance generated by finger contact.

In general, the resistive type and capacitive type display devices include a touch panel in addition to a display panel having upper and lower substrates. Accordingly, the entire optical characteristics of the display device may be substantially degraded and the thickness of the display device may be substantially increased.

Therefore, a sensor array substrate having an optical sensor formed on a display panel may be developed.

### SUMMARY OF THE INVENTION

Exemplary embodiments of the invention provide a display device having a sensor array substrate with improved display quality and minimized reduction in the display quality due to signal noise.

The above and other features of the invention will be described in or be apparent from the following description of exemplary embodiments.

In an exemplary embodiment, a sensor array substrate includes: a substrate; a protective substrate disposed on a first surface of the substrate; a plurality of light sensor units disposed on a second surface of the substrate, where the plurality of light sensor units detects reflection light reflected from a surface of the protective substrate; and a reflection light blocking pattern disposed between the light sensor units and the protective substrate, where the reflection light blocking pattern blocks a portion of the reflection light, and where a plurality of openings corresponding to the plurality of light sensor units is formed in the reflection light blocking pattern.

In another exemplary embodiment, a sensor array substrate includes: a substrate having a first surface and a second surface opposite to each other; a plurality of light sensor units disposed on the second surface of the substrate, where the plurality of light sensor units detects reflection light incident to the first surface of the substrate; and a reflection light blocking pattern disposed on the second surface of the, where a plurality of openings corresponding to the plurality of light sensor units is formed in the reflection light blocking pattern.

In still another exemplary embodiment, a display device includes: a sensor array substrate including a substrate, a protective substrate disposed on a first surface of the substrate, a plurality of light sensor units disposed on a second surface of the substrate, wherein the plurality of light sensor units detects reflection light reflected from a surface of the protective substrate, and a reflection light blocking pattern disposed between the light sensor units and the protective substrate, where the reflection light blocking pattern blocks a portion of the reflection light, and a plurality of openings corresponding to the plurality of light sensor units is formed in the reflection light blocking pattern; a display substrate disposed opposite to the sensor array substrate and including a pixel electrode; and a liquid crystal layer interposed between the sensor array substrate and the display substrate.

### BRIEF DESCRIPTION OF THE DRAWINGS

The above and other aspects and features of the present invention will become more apparent by describing in detail exemplary embodiments thereof with reference to the attached drawings, in which:

FIG. 1 is a top plan view of an exemplary embodiment of the sensor array substrate according to the present invention;

FIG. 2 is a cross sectional view taken along line A-A′ of the sensor array substrate of FIG. 1;

FIG. 3 is a cross sectional view of an exemplary embodiment of a display device including the sensor array substrate according to the present invention;

FIG. 4 is a conceptual diagram showing reflection lights reflected by a reflection light blocking pattern of an exemplary embodiment of the sensor array substrate;

FIGS. 5 to 9 illustrate cross sectional views illustrating an exemplary embodiment of a method of fabricating a sensor array substrate and a display device having the sensor array according to the present invention;

FIG. 10 is a top plan view of an alternative exemplary embodiment of the sensor array substrate;

FIG. 11 is a cross sectional view taken along line B-B′ of the sensor array substrate of FIG. 10;

FIG. 12 is a conceptual diagram showing reflection lights reflected by a reflection light blocking pattern of an alternative exemplary embodiment of the sensor array substrate;

FIG. 13 is a cross sectional view of another alternative exemplary embodiment of the sensor array substrate; and

FIGS. 14 to 16 are cross sectional views illustrating an alternative exemplary embodiment of the method of fabricating the sensor array substrate.

### DETAILED DESCRIPTION OF THE INVENTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the concept of the invention to those skilled in the art. In the drawings, sizes and relative sizes of layers and regions may be exaggerated for clarity.

It will be understood that when an element or layer is referred to as being “on” another element or layer, the element or layer can be directly on another element or layer or intervening elements or layers may also be present. In contrast, when an element is referred to as being “directly on” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Throughout the specification, like reference numerals in the drawings denote like elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross-section illustrations that are schematic illustrations of idealized embodiments. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region of and are not intended to limit the scope of the present claims.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, exemplary embodiments of a sensor array substrate, a display device having the same and a fabricating method thereof according to the present invention will be described with reference to the accompanying drawings.

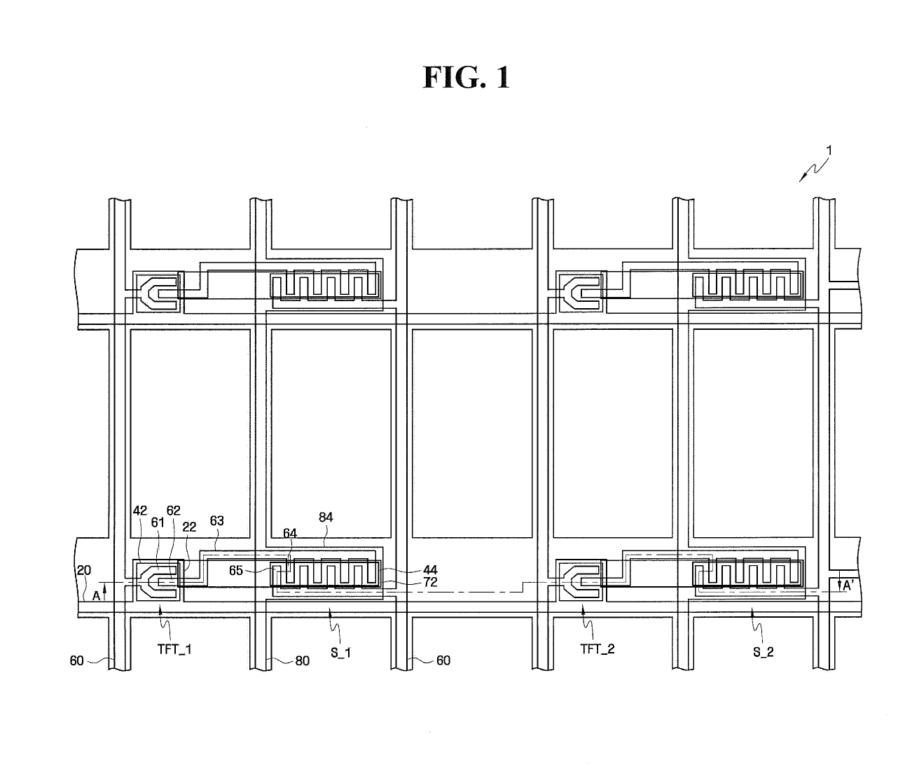

First, an exemplary embodiment of a sensor array substrate 1 and a display device having the sensor array substrate will be described with reference to FIGS. 1 to 4.

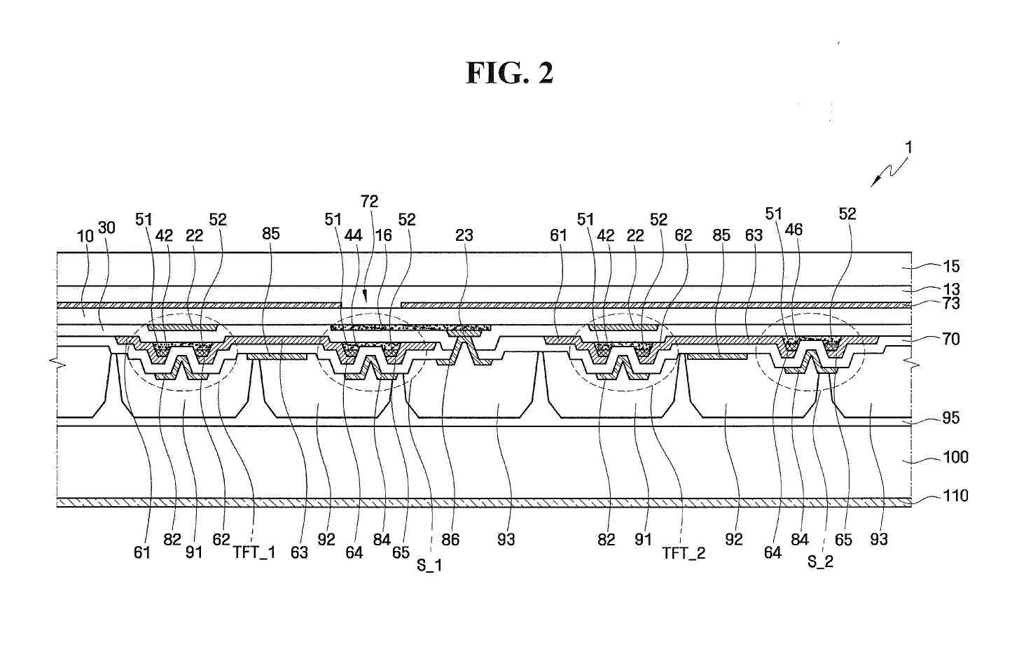

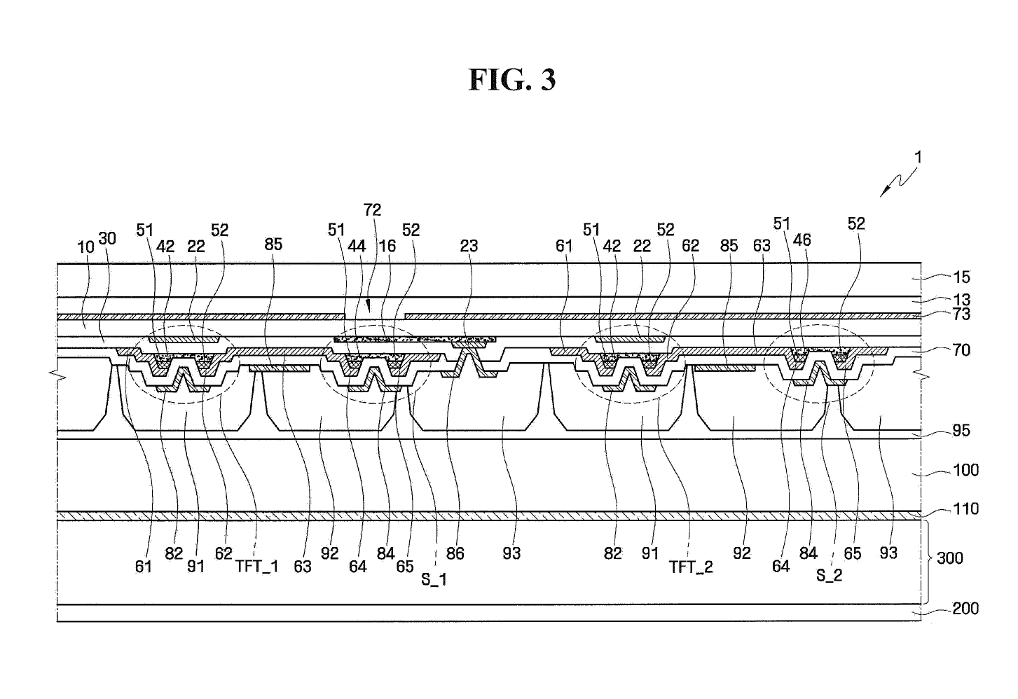

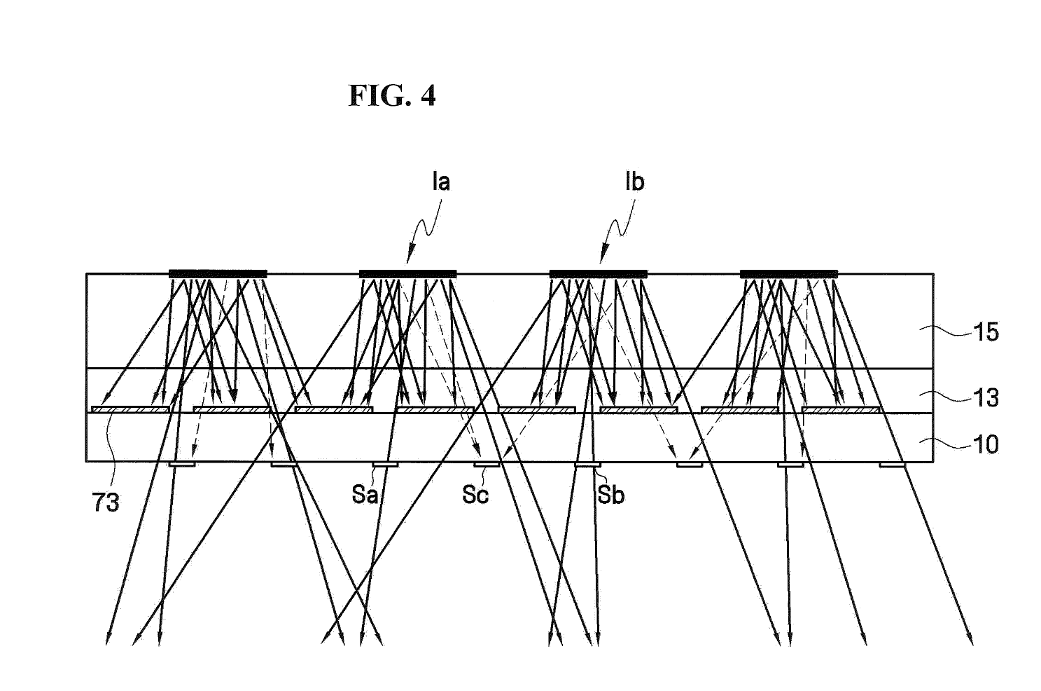

FIG. 1 is a top plan view of an exemplary embodiment of the sensor array substrate according to the present invention. FIG. 2 is a cross sectional view taken along line A-A′ of the sensor array substrate of FIG. 1. FIG. 3 is a cross sectional view of an exemplary embodiment of a display device including the sensor array substrate according to the present invention. FIG. 4 is a conceptual diagram showing reflection lights reflected by a reflection light blocking pattern of an exemplary embodiment of the sensor array substrate.

Referring to FIGS. 1 to 3, the sensor array substrate 1 includes a substrate 10, a protective substrate 15, a plurality of light sensor units and a reflection light blocking pattern 73 having an opening 72.

The protective substrate 15 is disposed on a first surface, e.g., the upper surface, of the substrate 10. The light sensor units are disposed on a second surface disposed opposite to the first surface, e.g., the lower surface, of the substrate 10, and detect a reflection light reflected from the first surface of the protective substrate 15.

The protective substrate 15 disposed on the first surface of the substrate 10 may protect the sensor array substrate 1 from an external impact or pressure. The protective substrate 15 may be formed of a material substantially the same as the material of the substrate 10. In an exemplary embodiment, the protective substrate 15 may be formed of glass or the like.

As shown in FIGS. 2 and 3, an adhesive layer 13 may be interposed between the substrate 10 and the protective substrate 15. In an exemplary embodiment, the substrate 10 and the protective substrate 15 may be optically bonded to each other by a material disposed therebetween and having a refractive index substantially identical or similar to the refractive index of the protective substrate 15. The material may be formed by being applied to a surface of the substrate. In an exemplary embodiment, an air layer may be formed between the substrate 10 and the protective substrate 15.

The light sensor units are disposed on the second surface of the substrate 10. In an exemplary embodiment, the light sensor units may include a first sensor unit S_1 and a second sensor unit S_2, a first thin film transistor TFT_1 and a second thin film transistor TFT_2.

A light blocking pattern 16 may be disposed on a region of the substrate 10 where the first sensor unit S_1 is disposed. In an exemplary embodiment, the light blocking pattern 16 may prevent visible light from being incident onto a first sensor semiconductor layer 44 of the first sensor unit S_1 and transmit infrared light.

In an exemplary embodiment, when the first sensor semiconductor layer 44 of the first sensor unit S_1 mainly detects infrared light, the first sensor semiconductor layer 44 may include a material having a small band gap. In this case, when visible light is incident onto the first sensor semiconductor layer 44, the first sensor semiconductor layer 44 may detect the visible light and generate a signal, and the first sensor unit S_1 may not appropriately function due to the visible incident thereto. In an exemplary embodiment, the light blocking pattern 16 may be provided to prevent the visible light from being incident to the first sensor unit S_1.

In an exemplary embodiment, when visible light is incident onto the light blocking pattern 16, the light blocking pattern 16 may generate a signal by a photovoltaic effect. Accordingly, the visible light is effectively prevented from being incident onto the first sensor semiconductor layer 44. The light blocking pattern 16 may include amorphous silicon (“a-Si”), amorphous silicon germanium (“a-SiGe”) or a material having a relatively high band gap compared to the band gap of the material of the first sensor semiconductor layer 44. The light blocking pattern 16 may have an insular form and may be disposed overlapping the first sensor semiconductor layer 44 such that the visible light is blocked from being incident onto the first sensor semiconductor layer 44. Further, a boundary of the first sensor semiconductor layer 44 may be disposed in a boundary of the light blocking pattern 16.

Gate wirings that transmit gate signals may be disposed on the substrate 10. The gate wirings may include a gate line 20 extending in a first direction, e.g., a horizontal direction, and gate electrodes 22 of thin film transistors TFT_1 and TFT_2, which are disposed protruding from the gate line 22.

A ground line 23 electrically connected to the light blocking pattern 16 may be disposed on the substrate 10. The ground line 23 may function to output a voltage generated from the light blocking pattern 16 that has absorbed visible light to a ground. Accordingly, the light blocking pattern 16 may be effectively prevented from functioning as a gate electrode of the first sensor unit S_1. That is, when the light blocking pattern 16 has absorbed visible light, the light blocking pattern 16 may generate a voltage by a photovoltaic effect. Accordingly, the light blocking pattern 16 may function as a gate electrode in the first sensor unit S_1 and may cause a malfunction of the first sensor unit S_1. Therefore, the ground line 23 may be provided to prevent the malfunction of the first sensor unit S_1 due to the light blocking pattern 16. In an exemplary embodiment, the ground line 23 may be disposed extending in a first direction substantially in parallel with the gate line 20, e.g., in a horizontal direction of the substrate 10.

A gate insulating film 30 may be disposed on the substrate 10, the light blocking pattern 16, the gate electrode 22 and the ground line 23. In an exemplary embodiment, the gate insulating film 30 may include a material, such as silicon oxide (SiOx), silicon nitride (SiNx), or the like.

A semiconductor layer 42 including a semiconductor material, such as hydrogenated amorphous silicon and polycrystalline silicon, for example, may be disposed on the gate insulating film 30 overlapping the gate electrode 22. In an exemplary embodiment, the semiconductor layer 42 may have an insular form.

An ohmic contact layer 51 and 52 may be disposed on the semiconductor layer 42 and may include a material, such as silicide or n+ hydrogenated amorphous silicon doped with n-type impurities in high concentration, for example.

In an exemplary embodiment, the first sensor semiconductor layer 44 and a second sensor semiconductor layer 46 included in the sensor units S_1 and S_2 to detect light may be disposed on the gate insulating film 30.

The first and second sensor semiconductor layers 44 and 46 may have a single-layer structure or a multilayer structure including amorphous silicon, amorphous silicon germanium or microcrystalline silicon (“mc-Si”).

In an exemplary embodiment, when the first sensor unit S_1 detects infrared light, the first sensor semiconductor layer 44 may include amorphous silicon germanium or microcrystalline silicon. When the second sensor unit S_2 detects visible light, the second sensor semiconductor layer 46 may include amorphous silicon or amorphous silicon germanium. In an exemplary embodiment, the first sensor semiconductor layer 44 may have a band gap smaller than a band gap of the second sensor semiconductor layer 46. Accordingly, the first sensor semiconductor layer 44 may detect infrared light to generate a signal, and the second sensor semiconductor layer 46 may detect visible light to generate a signal.

Ohmic contact patterns 51 and 52 including a material, such as silicide or n+ hydrogenated amorphous silicon doped with n-type impurities in high concentration, for example, may be disposed on the first and second sensor semiconductor layers 44 and 46.

A data wiring 60, 61, 62 and 63 may be disposed on the ohmic contact patterns 51 and 52. The data wiring 60, 61, 62 and 63 may include a data line 60, a source electrode 61, a drain electrode 62 and a drain electrode extension portion 63. The data line 60 extends in a second direction, e.g., in a vertical direction, and intersects the gate line 20. The source electrode 61 is protruded from the data line 60 to extend toward an upper portion of the semiconductor layer 42. The drain electrode 62 is disposed apart from the source electrode 61 on the semiconductor layer 42 to face the source electrode 61 around the gate electrode 22 or a channel region of the semiconductor layer 42, and the drain electrode extension portion 63 extends from the drain electrode 62 and is connected to a sensor source electrode 64. The data wiring 60, 61, 62 and 63 may be in direct contact with the ohmic contact patterns 51 and 52, as shown in FIG. 2 to thereby form an ohmic contact. Since the ohmic contact patterns 51 and 52 serve as an ohmic contact, the data wiring 60, 61, 62 and 63 may be a single layer including a low resistance material.

A sensing wiring 64 and 65 may be disposed on the gate insulating film 30 in parallel with the data wiring 60, 61, 62 and 63. The sensing wiring 64 and 65 may be connected to the drain electrode 62 via a sensing line (not shown) extending in a direction parallel to the data line and the drain electrode extension portion 63. The sensing wiring 64 and 65 may include a sensor source electrode 64 extending toward upper portions of the first and second sensor semiconductor layers 44 and 46, and a sensor drain electrode 65 protruded from the sensing line and extending to the upper portions of the first and second sensor semiconductor layers 44 and 46 to face the sensor source electrode 64.

The sensing wiring 64 and 65 may be in direct contact with the ohmic contact patterns 51 and 52, as shown in FIG. 2 to thereby form an ohmic contact. The sensing wiring 64 and 65 may include the same material having substantially the same structure as the structure of the data wiring 60, 61, 62 and 63.

A passivation film 70 may be disposed on the semiconductor layer 42, the first and second sensor semiconductor layers 44 and 46, the data wiring 60, 61, 62 and 63 and the sensing wiring 64 and 65. In an exemplary embodiment, the passivation film 70 may include an inorganic material, such as silicon nitride and silicon oxide, for example, an organic material having excellent planarization characteristics and photosensitivity, or a low-k insulating material formed by plasma enhanced chemical vapor deposition (“PECVD”), such as a-Si:C:O and a-Si:O:F.

The passivation film 70 may have a double layer structure including a lower inorganic layer and an upper organic layer to protect exposed portions of the semiconductor layer 42 and the first and second sensor semiconductor layers 44 and 46 while effectively using the characteristics of an organic layer.

A sensor gate electrode 84 may be disposed on the passivation film 70 overlapping the first and second sensor semiconductor layers 44 and 46. The sensor gate electrode 84 may supply a bias voltage to the first and second sensor units S_1 and S_2. In an exemplary embodiment, the sensor gate electrode 84 effectively prevents light emitted from a back light unit (not shown) from being incident onto the first and second sensor semiconductor layers 44 and 46. The sensor gate electrode 84 may include a material substantially the same as a material included in the gate line 20.

In an exemplary embodiment, first and second light blocking films 82 and 85 may be disposed on the passivation film 70. In this case, the first light blocking film 82 may be arranged overlapping the semiconductor layer 42 of the first and second thin film transistors TFT_1 and TFT_2. The second light blocking film 85 may be arranged overlapping the drain electrode extension portion 63. The first and second light blocking films 82 and 85 effectively prevents light emitted from the back light unit from being incident onto the semiconductor layer 42 and the drain electrode extension portion 63, and malfunctions of the first and second thin film transistors TFT_1 and TFT_2 and the first and second sensor units S_1 and S_2 are thereby effectively prevented. The first and second light blocking films 82 and 85 may include a material substantially the same as a material included in the gate line 20.

In an exemplary embodiment, a ground connection line 86 may be disposed on the passivation film 70. The ground connection line 86 may be connected to the ground line 23 through a via hole formed in the gate insulating film 30 and the passivation film 70. The ground connection line 86 may output a signal generated by the light blocking pattern 16 to a ground. The ground connection line 86 may include a material substantially the same as a material included in the gate line 20.

As described above, the first and second thin film transistors TFT_1 and TFT_2 may include the gate electrode 22, the gate insulating film 30, the semiconductor layer 42, the ohmic contact patterns 51 and 52, the source and drain electrodes 61 and 62, the drain electrode extension portion 63, and the passivation film 70, which are sequentially disposed on the substrate 10. In an exemplary embodiment, the first and second thin film transistors TFT_1 and TFT_2 may further include the first and second light blocking films 82 and 85.

In an exemplary embodiment, the first and second sensor units S_1 and S_2 may include the gate insulating film 30, the first and second sensor semiconductor layers 44 and 46, the sensor source electrode 64, the sensor drain electrode 65, the passivation film 70 and the sensor gate electrode 84, which are sequentially disposed on the substrate 10. In this case, the first sensor unit S_1 may include the light blocking pattern 16, the ground line 23 and the ground connection line 86.

Color filter layers 91, 92 and 93 may be disposed on the passivation film 70, the sensor gate electrode 84, the ground connection line 86 and the first and second light blocking films 82 and 85. The color filter layers 91, 92 and 93 allow the light transmitted through respective subpixel regions (now shown) to exhibit colors. The color filter layers 91, 92 and 93 may determine the color of light transmitted through a subpixel region defined on a display substrate 200 (see FIG. 3) facing the sensor array substrate and including a pixel electrode. In an exemplary embodiment, the subpixel region may correspond to one of red (“R”), green (“G”) and blue (“B”) colors.

In an exemplary embodiment, three subpixel regions may define a unit pixel region. That is, the unit pixel region may be defined by a region where the color filter layers 91, 92 and 93 are disposed. In an exemplary embodiment, when the color filter layers 91, 92 and 93 are disposed on the display substrate 200 (see FIG. 3), the sensor array substrate may not include the color filter layers 91, 92 and 93. In this case, however, a region on the sensor array substrate facing the color filter layers disposed on the display substrate 200 (see FIG. 3) may be defined as a unit pixel region.

A black matrix 95 may be disposed on the color filter layers 91, 92 and 93.

The black matrix 95 may function as a light blocking film and effectively prevent leakage of light in a region except the pixel region to improve the image quality. As shown in FIG. 1, the black matrix 95 may be disposed in a non-pixel region where the gate electrode 22, the source electrode 61, the drain electrode 62 and the like are disposed. Further, the black matrix 95 may be disposed overlapping the gate line and/or the data line to maximize an opening ratio. In an exemplary embodiment, the black matrix 95 may include an opaque material, such as chromium (Cr), for example.

An overcoat layer 100 for planarization may be disposed on the color filter layers 91, 92 and 93 and the black matrix 95. The overcoat layer 100 may include a material having a relative dielectric constant in a range from about 3.0 to about 3.5 to reduce a parasitic capacitance between a common electrode 110 and the lines included in the first and second thin film transistors TFT_1 and TFT_2 and the first and second sensor units S₁ and S_2. In an exemplary embodiment, the overcoat layer 100 may include an organic film or inorganic film. In an exemplary embodiment, the overcoat layer 100 may include an organic film for the planarization thereof. In this case, the overcoat layer 100 may be formed of a transparent organic material.

The common electrode 110 may be disposed on the overcoat layer 100. The common electrode 110 may apply a common voltage to a liquid crystal layer 300 (see FIG. 3). The common electrode 110 may include a transparent conductive material, e.g., indium tin oxide (“ITO”), indium zinc oxide (“IZO”), zinc oxide (ZnO) or the like.

The reflection light blocking pattern 73 is disposed between the light sensor units S_1 and S_2 and the protective substrate 15. The reflection light blocking pattern 73 includes the opening 72 corresponding to each of the light sensor units S_1 and S_2 and blocks a portion of the reflected light reflected from the surface of the protective substrate 15.

As shown in FIG. 2, the reflection light blocking pattern 73 may be disposed on a first surface, e.g., a lower surface, of the substrate 10. The opening 72 of the reflection light blocking pattern 73 corresponds to each of the light sensor units S_1 and S_2. In an exemplary embodiment, the opening 72 of the reflection light blocking pattern 73 may expose the first sensor semiconductor layer 44 of the first sensor unit S_1.

As shown in FIGS. 1 to 4, the reflection light blocking pattern 73 may be dispose substantially on the entire first surface of the substrate 10, that is, the reflection light blocking pattern 73 covers a region except a portion of the first surface of the substrate 10 where the opening 72 of the reflection light blocking pattern 73 is disposed, i.e., the portion corresponding to the light sensor units S_1 and S_2, e.g., the first sensor semiconductor layer 44 of the first sensor unit S_1. In this case, the reflection light blocking pattern 73 may include a material that transmits visible light and blocks infrared light.

As shown in FIG. 4, the light emitted from the back light unit may pass through the substrate 10, the adhesive layer 13 and the protective substrate 15 toward a surface of the protective substrate 15. In this case, the light incident to the surface of the protective substrate 15 may be reflected diffusely by image patterns Ia and Ib disposed on the surface of the protective substrate 15. Specifically, the diffused reflection may occur on the surface having the image patterns Ia and Ib, and the light may be emitted to an outside through the protective substrate 15 on the surface having no image patterns Ia and Ib.

When the diffused reflection occurs by the image patterns Ia and Ib on the surface of the protective substrate 15, reflection light, e.g., infrared light, may be generated. The reflection light may pass through the protective substrate 15 again to be incident onto the substrate 10.

In an exemplary embodiment, as shown in FIG. 4, the reflection light may travel in a random direction by the diffused reflection occurring in the first image pattern Ia. Accordingly, the reflection light generated in the first image pattern Ia may include not only reflection light (solid lines) traveling to the first sensor unit Sa corresponding to the first image pattern Ia, but also reflection light (dotted lines) traveling to a third sensor unit Sc that does not correspond to the first image pattern Ia. Similarly, the reflection light generated in the second image pattern Ib may include not only reflection light (solid lines) traveling to the second sensor unit S_2 corresponding to the second image pattern Ib, but also reflection light (dotted lines) traveling to the third sensor unit Sc that does not correspond to the second image pattern Ib.

As shown in FIG. 4, the reflection light blocking pattern 73 including the opening 72 (see FIG. 2) corresponding to each of the sensor units S_1 and S_2 is disposed on the substrate 10, thereby blocking the reflection light (dotted lines) traveling to the sensor unit that does not correspond to each of the image patterns Ia and Ib. Accordingly, a degradation of the display quality due to signal noise and image blurring is substantially reduced or effectively prevented.

In an exemplary embodiment, the sensor units S_1 and S_2 include the first sensor unit S_1 that detects infrared light, and the opening 72 of the reflection light blocking pattern 73 is arranged to correspond to only the first sensor unit S_1. However, the scope of the present invention is not limited to the exemplary embodiments described above, and various modifications may be made within the scope of the present invention for various types of the display device, i.e., the types of light provided from the back light unit and the types of the reflection light from the image patterns.

In an exemplary embodiment, as shown in FIG. 3, the display includes the display substrate 200 disposed opposite to, e.g., facing, the sensor array substrate 1 and including a pixel electrode (not shown), and the liquid crystal layer 300 interposed between the sensor array substrate 1 and the display substrate 200.

Specifically, the display substrate 200 may face the sensor array substrate 1 and include the pixel electrode (not shown). The pixel electrode may be connected to a switching element. The switching element may adjust a voltage that is applied to the pixel electrode. The liquid crystal of the liquid crystal layer 300 is driven by the voltage applied to the pixel electrode and the voltage applied to the common electrode 110, and the amount of transmitted light is thereby adjusted.

The liquid crystal layer 300 may be interposed between the sensor array substrate 1 and the display substrate 200. Light transmittance of the liquid crystal layer 300 may be adjusted by a voltage difference between the pixel electrode and the common electrode 110.

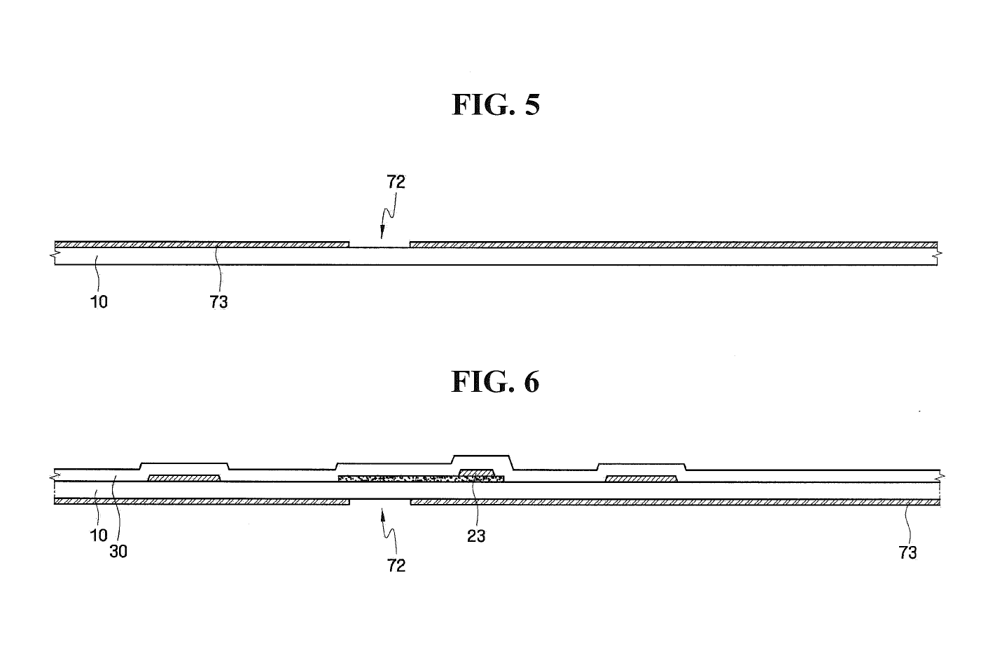

Hereinafter, exemplary embodiment of a method of fabricating a sensor array substrate and a display device having the sensor array substrate according to the present invention will be described with reference to FIGS. 5 to 9. FIGS. 5 to 9 illustrate cross sectional views illustrating an exemplary embodiment of a method of fabricating a sensor array substrate and a display device having the sensor array substrate according to the present invention.

Referring to FIG. 5, the reflection light blocking pattern 73 including the opening 72 is provided, e.g., formed, on a first surface of the substrate 10.

In an exemplary embodiment, a material for the reflection light blocking pattern may be deposited on the first surface of the substrate 10 to form a reflection light blocking film (not shown). Then, the reflection light blocking pattern 73 including the opening 72 may be provided, e.g., formed by patterning the reflection light blocking film. In this case, the opening 72 may be formed to correspond to a predetermined region, e.g., a region where the first sensor unit S_1 is disposed. In an exemplary embodiment, the opening 72 may be formed to correspond to a region where each of the first and second sensor units S_1 and S_2 is disposed.

Subsequently, referring to FIG. 6, the light blocking pattern 16, the gate electrode 22 and the ground line 23 and the gate insulating film 30 are sequentially provided, e.g., formed, on a second surface of the substrate 10.

Specifically, an amorphous silicon film may be provided on the second surface of the substrate 10, e.g., formed on the second surface of the substrate 10 by depositing, e.g., amorphous silicon on an entire first surface of the substrate 10 by plasma enhanced chemical vapor deposition. Then, the light blocking pattern 16 may be provided, e.g., formed, by patterning the amorphous silicon. In this case, the light blocking pattern 16 may be formed on a region where the first sensor unit S_1 is disposed.

Then, after a conductive film for a gate wiring and ground line are deposited, the gate line 20 (see FIG. 1), the gate electrode 22 and the ground line 23 may be formed by patterning the conductive film. In this case, the gate electrode 22 may be formed a region where the first and second thin film transistors TFT_1 and TFT_2 are disposed. The ground line 23 may be formed in contact with the light blocking pattern 16.

Subsequently, the gate insulating film 30 may be provided on the substrate 10, the gate electrode 22 and the ground line 23, e.g., deposited on the substrate 10, the gate electrode 22 and the ground line 23 by, e.g., plasma enhanced chemical vapor deposition or reactive sputtering. The gate insulating film 30 may include at least one of, e.g., silicon nitride (SiNx), silicon oxide (SiOx), silicon oxynitride (SiON) and SiOC.

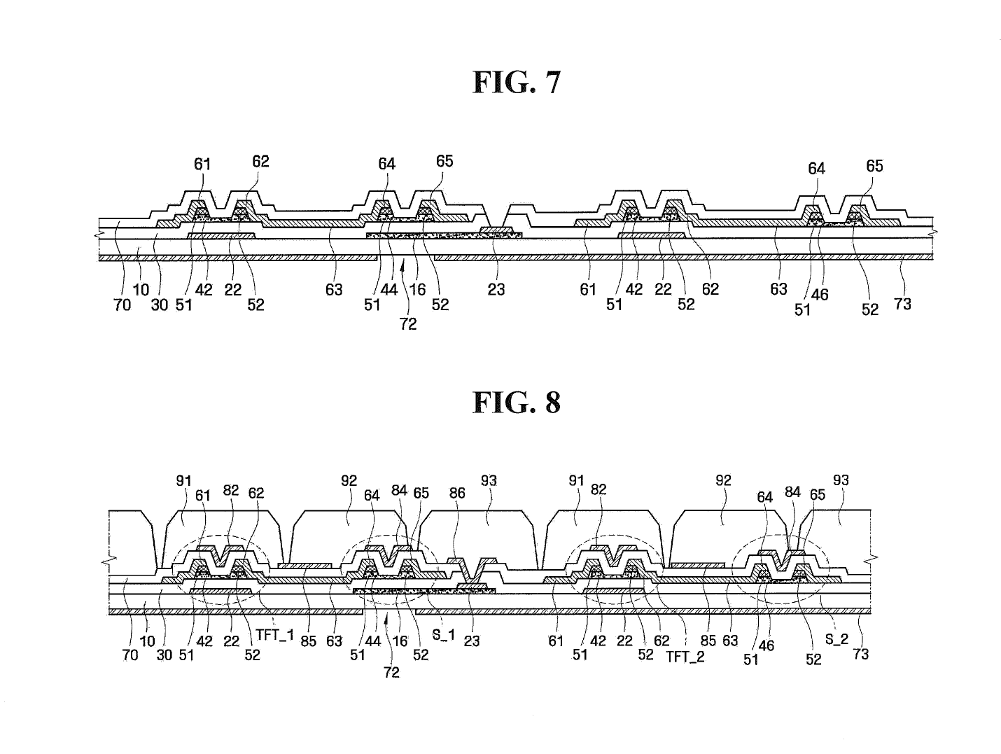

Referring to FIG. 7, the semiconductor layer 42 may be provided on the gate insulating film 30 to overlap the gate electrode 22. Further, the first sensor semiconductor layer 44 may be provided on the gate insulating film 30 to overlap the light blocking pattern 16. The first sensor semiconductor layer 44 may include a material, such as amorphous silicon germanium, for example. Further, the second sensor semiconductor layer 46 may include a material, such as amorphous silicon, for example.

Subsequently, the ohmic contact patterns 51 and 52 may be provided, e.g., formed, on the semiconductor layer 42 and the first and second sensor semiconductor layers 44 and 46. Then, after a conductive film for a data wiring and sensing wiring is deposited on the ohmic contact patterns 51 and 52, the conductive film is patterned to thereby form the data wiring 60, 61, 62 and 63 including the data line 60 (see FIG. 1), the source electrode 61, the drain electrode 62 and the drain electrode extension portion 63 extending from the drain electrode 62 to be connected to the sensor source electrode 64. Further, the sensing wiring 64 and 65 including the sensor source electrode 64 and the sensor drain electrode 65 may be formed.

Subsequently, the passivation film 70 may be deposited by, e.g., plasma enhanced chemical vapor deposition. The passivation film 70 may include a material, such as silicon nitride (SiNx) or silicon oxide (SiOx), for example. Then, a via hole may be formed by patterning the gate insulating film 30 and the passivation film 70. The upper surface of the ground line 23 may be partially exposed through the via hole.

Subsequently, referring to FIG. 8, a conductive film for a sensor gate electrode, first and second light blocking films and a ground connection line may be deposited and patterned to thereby form the sensor gate electrode 84, the first and second light blocking films 82 and 85 and the ground connection line 86.

The first and second thin film transistors TFT_1 and TFT_2 and the first and second sensor units S_1 and S_2 may be formed through a method substantially similar to the method described above.

Subsequently, the color filter layers 91, 92 and 93 may be provided on the passivation film 70, the sensor gate electrode 84, the ground connection line 86 and the first and second light blocking films 82 and 85, using at least one of a photolithography method, a screen printing method, a gravure printing method and a printing method using a material for formation of color filter layers and an inkjet print device.

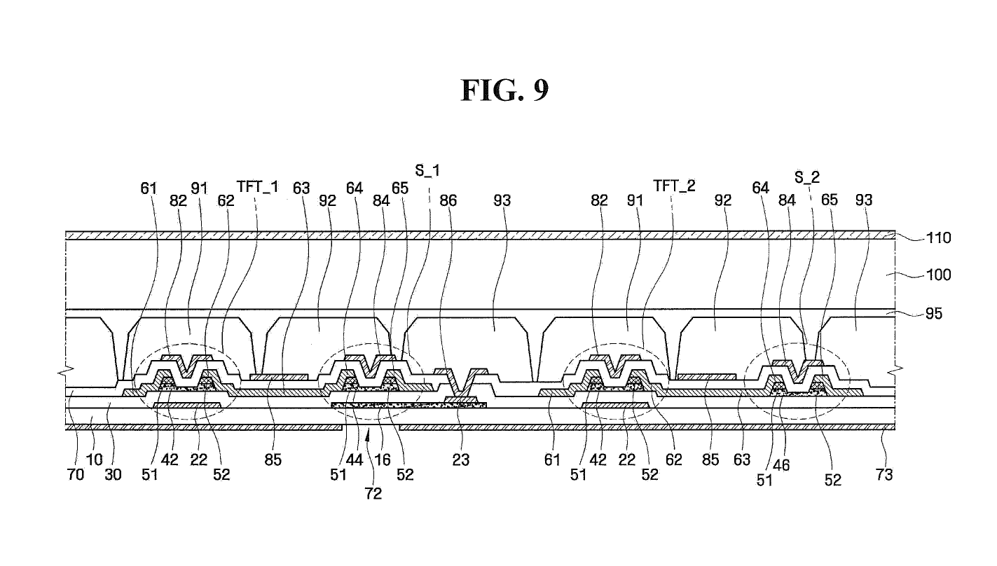

Subsequently, referring to FIG. 9, the black matrix 95 and the overcoat layer 100 may be provided on the color filter layers 91, 92 and 93. In an exemplary embodiment, the black matrix 95 may be formed on the color filter layers 91, 92 and 93 by, e.g., sputtering. The black matrix 95 may include a material that blocks light provided from the back light unit, e.g., a metal material.

Thereafter, the overcoat layer 100 may be formed by depositing an organic film on the substrate 10 with the color filter layers 91, 92 and 93, and the black matrix 95 formed thereon by, e.g., plasma enhanced chemical vapor deposition. Then, the common electrode 110 may be formed by depositing ITO, IZO or the like on the overcoat layer 100 by, e.g., sputtering.

As described above, an exemplary embodiment of the sensor array substrate according to the present invention may be fabricated.

Referring back to FIG. 3, the display substrate 200 including a pixel electrode may be arranged facing the sensor array substrate 1, and the liquid crystal layer 300 may be provided, e.g., injected, between the sensor array substrate 1 and the display substrate 200 to manufacture an exemplary embodiment of the display device according to the present invention.

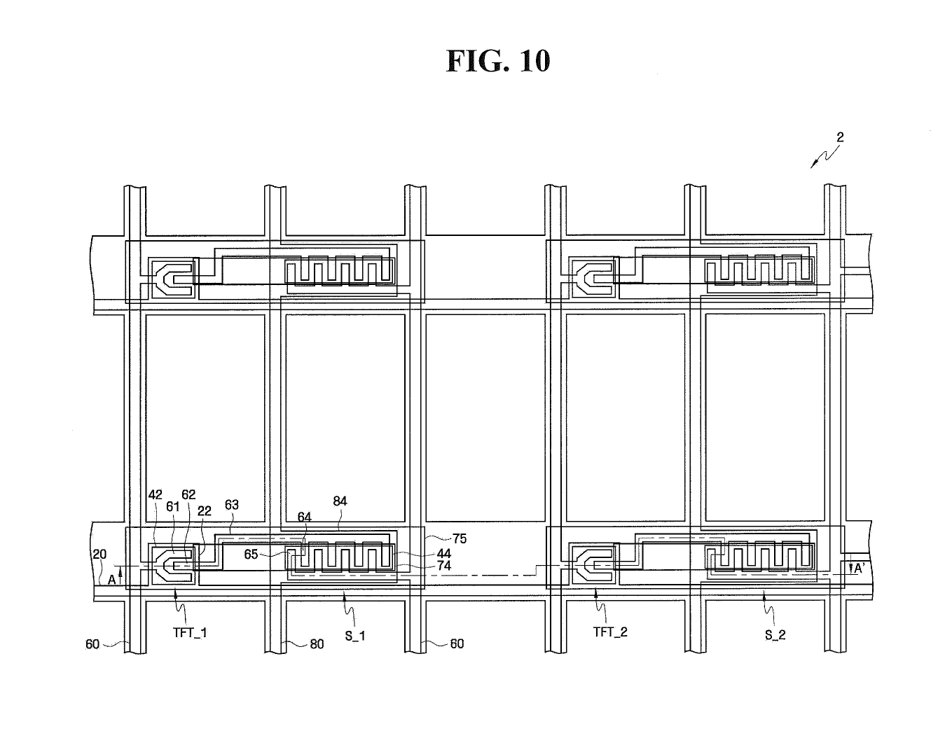

Hereinafter, an alternative exemplary embodiment of a sensor array substrate 2, a display device having the sensor array substrate and a fabricating method thereof will be described with reference to FIGS. 10 to 12.

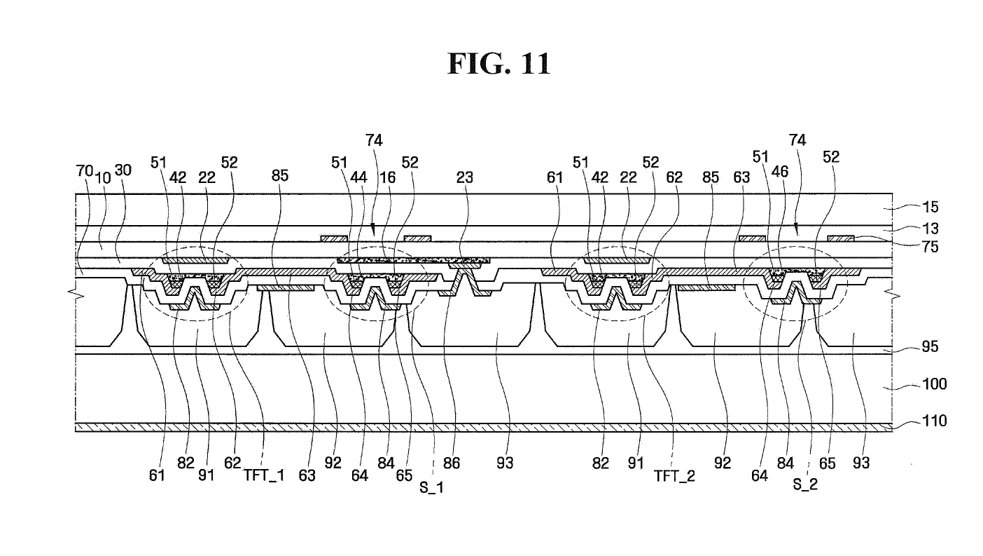

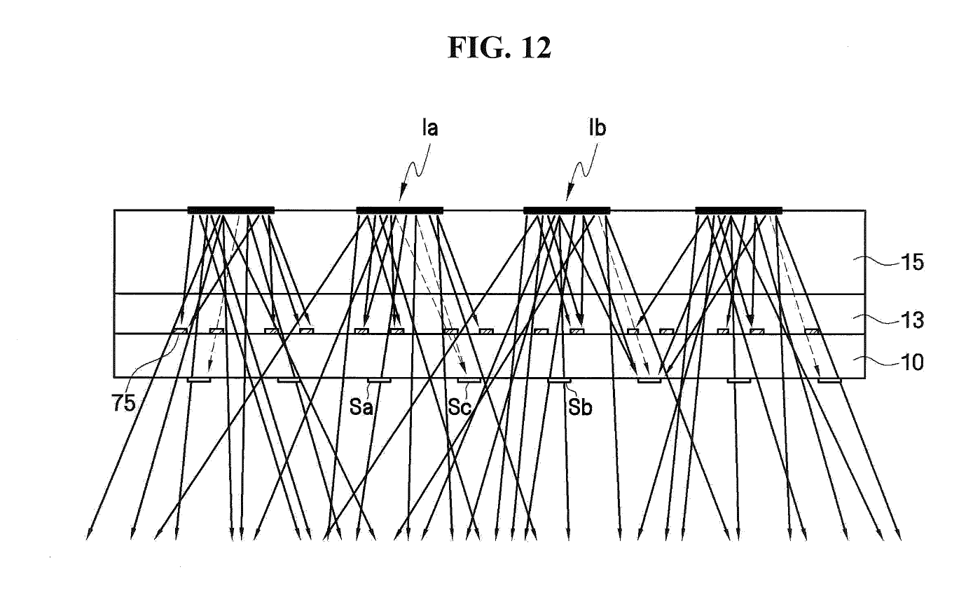

FIG. 10 illustrates a top plan view of an alternative exemplary embodiment of the sensor array substrate 2. FIG. 11 is a cross sectional view taken along line A-A′ of the sensor array substrate of FIG. 10. FIG. 12 is a conceptual diagram showing reflection lights reflected by a reflection light blocking pattern of an alternative exemplary embodiment the sensor array substrate.

The sensor array substrate 2 in FIGS. 10 and 11 is substantially the same as the sensor array substrate 1 in FIGS. 1 and 2 except for a plurality of slit patterns 75 formed with reflection light blocking patterns disposed separate from each other. The same or like elements shown in FIGS. 10 and 11 have been labeled with the same reference characters as used above to describe the exemplary embodiments of the sensor array substrate in FIGS. 1 and 2, and any repetitive detailed description thereof will hereinafter be omitted or simplified. Referring to FIGS. 10 and 11, the reflection light blocking pattern of the sensor array substrate 2 includes a plurality of slit patterns 75 disposed apart from each other on one surface of the substrate 10. In this case, each of the slit patterns 75 may include an opening 74 therein and correspond to each of the light sensor units S_1 and S_2.

In an exemplary embodiment, each of the slit patterns 75 may have a closed shape surrounding the opening 74. That is, each of the slit patterns 75 may include the opening 74 formed in an insular form.

Further, as shown in FIG. 10, the opening 74 of the each of the slit patterns 75 may be arranged to correspond to each of the light sensor units S_1 and S_2. The light sensor units S_1 and S_2, e.g., the sensor semiconductor layers 44 and 46 that detect the reflection light, may be exposed through the opening 74. In an exemplary embodiment, each of the slit patterns 75 may have a rectangular shape surrounding each of the light sensor units S_1 and S_2. In an exemplary embodiment, the slit patterns 75 having the opening 74 are arranged to correspond to both the first sensor unit S_1 that detects infrared light and the second sensor unit S_2 that detects visible light, as shown in FIG. 10. In an alternative exemplary embodiment, the slit pattern may be omitted in the second sensor unit S_2 that detects visible light.

Further, the slit patterns 75 may overlap the black matrix 95 disposed on the light sensor units S_1 and S_2. In an exemplary embodiment, the boundaries of the slit patterns 75 are arranged corresponding to the boundary of the black matrix 95. In an alternative exemplary embodiment, the boundaries of the slit patterns 75 are arranged within the boundary of the black matrix 95 such that the boundaries of the slit patterns 75 may not protrude from the black matrix 95.

As shown in FIG. 10, when viewed in the layout, the slit patterns 75 may be disposed within a region where the black matrix 95 is disposed. In an exemplary embodiment, the slit patterns 75 may include a material that blocks both visible light and infrared light, e.g., a metal material.

As described with reference to FIG. 4, referring to FIG. 12, the light emitted from the back light unit may pass through the substrate 10, the adhesive layer 13 and the protective substrate 15, and the light passed through the protective substrate 15 may be reflected diffusely by the image patterns Ia and Ib disposed on the surface of the protective substrate 15.

When the diffused reflection occurs by the image patterns Ia and Ib on the surface of the protective substrate 15, reflection light, e.g., infrared light, may be generated. The reflection light may pass through the protective substrate 15 again to be incident onto the substrate 10. In this case, as shown in FIG. 12, the reflection light generated in the first image pattern Ia may travel in a random direction. Accordingly, the reflection light generated in the first image pattern Ia may include not only reflection light (solid lines) traveling to the first sensor unit Sa corresponding to the first image pattern Ia, but also reflection light (dotted lines) traveling to the third sensor unit Sc that does not correspond to the first image pattern Ia. Similarly, the reflection light generated in the second image pattern Ib may include not only reflection light (solid lines) traveling to the second sensor unit S_2 corresponding to the second image pattern Ib, but also reflection light (dotted lines) traveling to the third sensor unit Sc that does not correspond to the second image pattern Ib.

As shown in FIG. 12, the slit patterns 75 including the opening 74 (see FIG. 11) corresponding to each of the sensor units S_1 and S_2 are arranged to block the reflection light (dotted lines) traveling to the sensor unit that does not correspond to each of the image patterns Ia and Ib due to scattering of light. Accordingly, a degradation of the display quality due to signal noise and image blurring is substantially reduced or effectively prevented.

In FIG. 12, the sensor units S_1 and S_2 including the first sensor unit S_1 that detects infrared light and the second sensor unit S_2 that detects visible light is described, and the slit patterns 75 including the opening 74 are arranged regardless of the first and second sensor units S_1 and S_2, but not being limited thereto. In alternative exemplary embodiments, various modifications may be made within the scope of the present invention for the types of the display device, i.e., the types of light provided from the back light unit and the types of the reflection light from the image patterns.

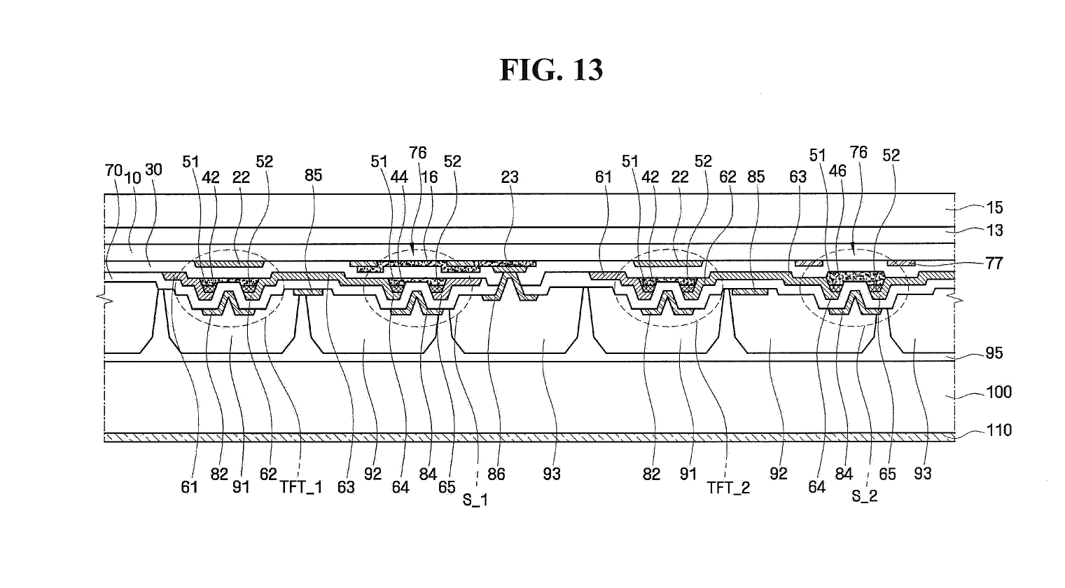

Hereinafter, alternative exemplary embodiments of a sensor array substrate 3 and a fabricating method thereof according to the present invention will be described with reference to FIGS. 13 to 16.

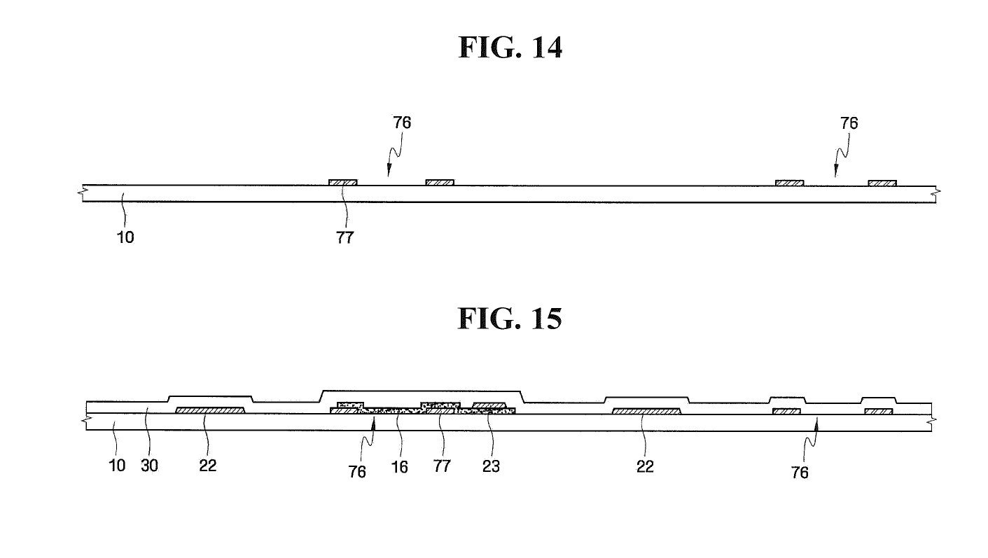

FIG. 13 is a cross sectional view of another alternative exemplary embodiment of the sensor array substrate 3 according to the present invention. FIGS. 14 to 16 are cross sectional views illustrating an alternative exemplary embodiment of a method of fabricating the sensor array substrate 3.

The sensor array substrate 3 in FIG. 13 is substantially the same as the sensor array substrates 1 and 2 shown in FIGS. 2 and 11 except that the reflection light blocking pattern includes a plurality of slit patterns 77 disposed apart from each other, and that the slit patterns 77 are arranged on the second surface of the substrate 10. The same or like elements shown in FIG. 13 have been labeled with the same reference characters as used above to describe the exemplary embodiments of the sensor array substrate in FIGS. 2 and 11, and any repetitive detailed description thereof will hereinafter be omitted or simplified.

Similarly, the exemplary embodiment of the fabricating method thereof shown in FIGS. 13 to 16 is substantially the same as the fabricating methods thereof shown in FIGS. 3 to 9.

First, referring to FIG. 13, the reflection light blocking pattern on the second surface of the substrate 10 includes a plurality of slit patterns 77 disposed apart from each other.

Specifically, the protective substrate 15 may be arranged on the first surface of the substrate 10. In this case, the adhesive layer 13 may be interposed between the first surface of the substrate 10 and the protective substrate 15. The slit patterns 77 are arranged on the second surface of the substrate 10. The second surface of the substrate 10 may be the surface of the substrate 10 opposite to the first surface of the substrate 10 facing the protective substrate 15.

The slit patterns 77 include openings 76, and the light sensor units S_1 and S_2 may be arranged in the openings 76 of the slit patterns 77. In an exemplary embodiment, the openings 76 may expose the sensor semiconductor layers 44 and 46 of the light sensor units S_1 and S_2. As shown in FIG. 13, the sensor semiconductor layers 44 and 46 of the light sensor units S_1 and S_2 may be disposed corresponding to the openings 76 of the slit patterns 77. Further, the light blocking pattern 16 may be disposed on the slit patterns 77, and the ground line 23 may be disposed to be electrically connected to the light blocking pattern 16.

Hereinafter, an alternative exemplary embodiment of the method of fabricating the sensor array substrate 3 will be described with reference to FIGS. 14 to 16.

Referring to FIG. 14, the reflection light blocking pattern including the slit patterns 77 is provided, e.g., formed, on the second surface of the substrate 10 opposite to the first surface of the substrate 10 on which the protective substrate 15 is disposed. In an exemplary embodiment, the slit patterns 77 may be arranged to correspond to the respective regions where the light sensor units S_1 and S_2 are disposed. Further, the slit patterns 77 may include the openings 76, and the openings 76 may be formed to correspond to the light sensor units S_1 and S_2, e.g., the sensor semiconductor layers 44 and 46.

Subsequently, referring to FIG. 15, the light blocking pattern 16, the gate electrode 22, the ground line 23 and the gate insulating film 30 are sequentially provided on the second surface of the substrate 10 on which the slit patterns 77 are disposed.

Specifically, a deposition film for a light blocking pattern may be disposed, e.g., deposited, on the second surface of the substrate 10 with the slit patterns 77 formed thereon, and patterned to form the light blocking pattern 16. The light blocking pattern 16 may be selectively provided, e.g., formed, on a region, e.g., where the first sensor unit S_1 that detects infrared light is disposed. A process of forming the gate electrode 22, the ground line 23 and the gate insulating film 30 is substantially the same as the process described above, and any repetitive detailed description thereof will be omitted.

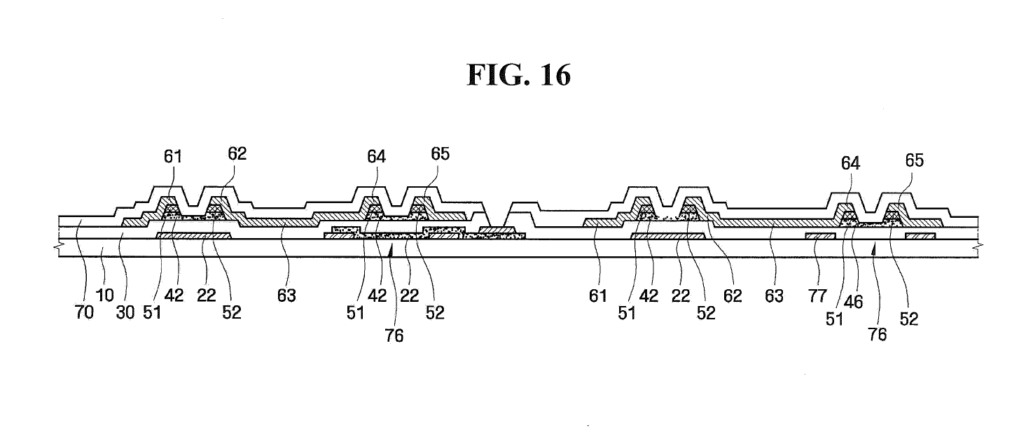

Subsequently, referring to FIG. 16, the semiconductor layer 42 may be provided, e.g., formed, on the gate insulating film 30 to overlap the gate electrode 22. Further, the first sensor semiconductor layer 44 may be provided on the gate insulating film 30 to overlap the light blocking pattern 16. Further, the first and second sensor units S_1 and S_2 including the first and second sensor semiconductor layers 44 and 46 may be provided to correspond to the slit patterns 77, respectively. Specifically, the first and second sensor semiconductor layers 44 and 46 of the first and second sensor units S_1 and S_2 may be arranged at the openings 76 of the slit patterns 77, respectively.

Subsequently, referring again to FIG. 13, the sensor array substrate 3 and the display device including the sensor array substrate 3 may be fabricated by the subsequent steps substantially the same as to corresponding steps of the exemplary embodiments described above. In this case, the slit patterns 77 disposed on the second surface of the substrate 10 may be arranged to overlap the black matrix 95 disposed on the light sensor units S_1 and S_2. In an exemplary embodiment, the slit patterns 77 may be arranged at the end of the black matrix 95. In another exemplary embodiment, the slit patterns 77 may be provided not to protrude from the black matrix 95. That is, when viewed in the layout, the slit patterns 77 may be formed within a region where the black matrix 95 is disposed.

As described above, the slit patterns 77 are disposed on the second surface of the substrate 10 on which the light sensor units S_1 and S_2 are disposed. Accordingly, when the light is scattered by the image pattern, the light traveling to the sensor unit that does not correspond to the corresponding image pattern is effectively blocked, and a sensing position is thereby substantially accurately detected.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A sensor array substrate comprising:
a substrate;
a protective substrate disposed on a first surface of the substrate;
a plurality of light sensor units disposed on a second surface of the substrate, wherein the plurality of light sensor units detects reflection light reflected from a surface of the protective substrate; and
a reflection light blocking pattern disposed between the plurality of light sensor units and the protective substrate,
wherein the reflection light blocking pattern blocks a portion of the reflection light, and
wherein a plurality of openings corresponding to the plurality of light sensor units is formed in the reflection light blocking pattern.

2. The sensor array substrate of claim 1, wherein the reflection light blocking pattern is disposed on the first surface of the substrate.

3. The sensor array substrate of claim 1, further comprising an adhesive layer interposed between the substrate and the protective substrate.

4. The sensor array substrate of claim 1, wherein
each of the plurality of light sensor units comprises a sensor semiconductor layer which detects the reflection light, and
each of the plurality of openings of the reflection light blocking pattern exposes the sensor semiconductor layer of each of the plurality of light sensor.

5. The sensor array substrate of claim 1, wherein the reflection light blocking pattern is disposed overlapping substantially an entire of the first surface of the substrate.

6. The sensor array substrate of claim 5, wherein the reflection light blocking pattern includes a material which transmits visible light and blocks infrared light.

7. The sensor array substrate of claim 1, wherein
the reflection light blocking pattern includes a plurality of slit patterns disposed apart from each other,
the plurality of slit patterns corresponds to the plurality of light sensor units, and
each of the plurality of slit patterns includes an opening of the plurality of openings therein.

8. The sensor array substrate of claim 7, wherein each of the plurality of slit patterns has a closed shape surrounding the opening.

9. The sensor array substrate of claim 7, further comprising a black matrix disposed on the plurality of light sensor units, wherein each of the plurality of slit patterns overlaps the black matrix.

10. The sensor array substrate of claim 9, wherein each of the plurality of slit patterns includes a metal material.

11. The sensor array substrate of claim 7, wherein
the plurality of slit patterns is disposed on the second surface of the substrate, and
each of the plurality of light sensor units is disposed in the opening of each of the plurality of slit patterns.

12. The sensor array substrate of claim 1, wherein
each of the plurality of light sensor units comprises:
a first sensor unit which detects infrared light; and
a second sensor unit which detects visible light, and
each of the plurality of openings of the reflection light blocking pattern is arranged to correspond to the first sensor unit.

13. A sensor array substrate comprising:
a substrate having a first surface and a second surface opposite to each other;
a plurality of light sensor units disposed on the second surface of the substrate, wherein the plurality of light sensor units detects reflection light incident to the first surface of the substrate; and
a reflection light blocking pattern disposed on the second surface of the substrate, wherein a plurality of openings corresponding to the plurality of light sensor units is formed in the reflection light blocking pattern.

14. The sensor array substrate of claim 13, further comprising a protective substrate disposed on the first surface of the substrate, wherein the reflection light blocking pattern is disposed between the light sensor units and the protective substrate.

15. The sensor array substrate of claim 13, wherein
each of the plurality of light sensor units comprises a sensor semiconductor layer which detects the reflection light, and
each of the plurality of openings formed in the reflection light blocking pattern exposes the sensor semiconductor layer of each of the plurality of light sensor units.

16. The sensor array substrate of claim 13, wherein
the reflection light blocking pattern includes a plurality of slit patterns formed apart from each other,
the plurality of slit patterns corresponds to the plurality of light sensor units, and
each of the plurality of slit patterns includes an opening of the plurality of openings therein.

17. The sensor array substrate of claim 16, further comprising a black matrix disposed on the light sensor units, wherein each of the plurality of slit patterns overlaps the black matrix.

18. The sensor array substrate of claim 17, wherein each of the plurality of slit patterns includes a metal material.

19. A display device comprising:
a sensor array substrate comprising:
a substrate;
a protective substrate disposed on a first surface of the substrate;
a plurality of light sensor units disposed on a second surface of the substrate, wherein the plurality of light sensor units detects reflection light reflected from a surface of the protective substrate; and
a reflection light blocking pattern disposed between the light sensor units and the protective substrate, wherein the reflection light blocking pattern blocks a portion of the reflection light, and a plurality of openings corresponding to the plurality of light sensor units is formed in the reflection light blocking pattern; and
a display substrate disposed opposite to the sensor array substrate and including a pixel electrode; and
a liquid crystal layer interposed between the sensor array substrate and the display substrate.

20. The display device of claim 19, wherein
the reflection light blocking pattern includes a plurality of slit patterns disposed apart from each other,
the plurality of slit patterns corresponds to the plurality of light sensor units, respectively,
each of the plurality of slit patterns includes an opening of the plurality of openings therein, and
an entire of each of the plurality of slit patterns overlaps a black matrix.
